(19) United States
(12) Patent Application Publication
(10) Pub. No.: US 2013/0078774 A1
(43) Pub. Date: Mar. 28, 2013

(54) METHOD FOR FORMING DOPE REGIONS WITH RAPID THERMAL PROCESS

(71) Applicants: Jeng-Hsing Jang, Taoyuan County (TW); Yi-Nan Chen, Taoyuan County (TW); Hsien-Wen Liu, Taoyuan County (TW)

(72) Inventors: Jeng-Hsing Jang, Taoyuan County (TW); Yi-Nan Chen, Taoyuan County (TW); Hsien-Wen Liu, Taoyuan County (TW)

(73) Assignee: NANYA TECHNOLOGY CORPORATION, TAOYUAN (TW)

(21) Appl. No.: 13/240,931

(22) Filed: Sep. 22, 2011

(51) Int. Cl. H01L 21/336; H01L 21/8238

(52) U.S. Cl. 438/231; 438/305; 257/E21.409; 257/E21.634

(57) ABSTRACT

The invention provides a method for forming a semiconductor device, including providing a substrate, forming a gate dielectric layer, forming a gate electrode on the gate dielectric layer, forming a spacer on sidewalls of the gate dielectric layer and the gate electrode, and using a rapid thermal process (RTP) apparatus comprising a plurality of lamps and a bias applying system to dope the substrate to form a source/drain region, wherein in the RTP apparatus, gaseous dopant species are illuminated by the lamps to be excited for transference gaseous dopant species to dopant ions and the dopant ions are moved by a bias from the bias applying system to be doped into the substrate.

### BACKGROUND OF THE INVENTION

1. Field of the Invention

The present invention relates generally to integrated circuit manufacturing and more particularly to a rapid thermal process with a gaseous dopant species.

2. Description of the Related Art

A metal-oxide semiconductor field-effect transistor (MOSFET) uses a gate to control an underlying surface channel joining a source and a drain. The channel, source and drain are located within a semiconductor substrate, with the source and drain being doped oppositely to the substrate. The gate is separated from the semiconductor substrate by a thin insulating layer such as a gate oxide. The operation of the MOSFET involves application of an input voltage to the gate, which sets up a transverse electric field in the channel in order to modulate the longitudinal conductance of the channel. Within a transistor, each of the source and drain meets the substrate underneath the gate at what is known as a junction. For example, the substrate may be a p-type semiconductor material, while the source and the drain may be doped such that they are n-type semiconductor material. The contact between the n-type semiconductor material and the p-type semiconductor material is thus called the p-n junction.

Commonly, devices such as microprocessors for personal computers include a plurality of transistors. Desirably, these transistors have shallow depletion regions, or “shallow junctions” for advanced semiconductor generation. The current and main technique used for forming a junction is ion implantation. However, it is getting harder for ion implantation to achieve shallow junctions of devices below the 90 nm generation. In addition, conventional ion implantation processes generate silicon damage that requires a thermal treatment for repair.

### BRIEF SUMMARY OF INVENTION

The invention provides a method for forming a semiconductor device, comprising providing a substrate, forming a gate dielectric layer, forming a gate electrode on the gate dielectric layer, forming a spacer on sidewalls of the gate dielectric layer and the gate electrode, and using a rapid thermal process (RTP) apparatus comprising a plurality of lamps and a bias applying system to dope the substrate to form a source/drain region, wherein in the RTP apparatus, gaseous dopant species are illuminated by the lamps to be excited for transference gaseous dopant species to dopant ions and the dopant ions are moved by a bias from the bias applying system to be doped into the substrate.

The invention further comprises a method for forming a semiconductor device, comprising the following steps. A substrate comprising an NMOS region and a PMOS region is provided. A gate dielectric layer and a gate electrode are formed on the NMOS region and the PMOS region of the substrate. A first spacer layer is formed on the gate electrode and the substrate. A first photoresist layer is formed over the PMOS region of the substrate. The first spacer layer in the NMOS region is etched to form a first spacer using the first photoresist layer in the PMOS region as a mask. The first photoresist layer is removed. A rapid thermal process (RTP) apparatus comprising a plurality of lamps and a bias applying system is used to dope the substrate to form a first source/drain region in the NMOS region, wherein first gaseous dopant species are illuminated by the lamps to be excited for transference gaseous dopant species to first dopant ions and the first dopant ions are moved by a bias from the bias applying system to be doped into the NMOS region of substrate. A second spacer layer is formed over the NMOS region and the PMOS region of the substrate. A second photoresist layer is formed over the NMOS region of the substrate. The second spacer layer in the PMOS region is etched using the second photoresist layer as a mask. The first spacer layer in the PMOS region is etched to form a second spacer using the second photoresist layer in the NMOS region as a mask. The second photoresist layer is removed. The rapid thermal process (RTP) apparatus is used to dope the substrate to form a source/drain region in the PMOS region, wherein second gaseous dopant species are illuminated by the lamps to be excited for transference gaseous dopant species to second dopant ions and the second dopant ions are moved by a bias from the bias applying system to be doped into the PMOS region of substrate.

### BRIEF DESCRIPTION OF DRAWINGS

The invention can be more fully understood by reading the subsequent detailed description and examples with references made to the accompanying drawings, wherein,

FIG. 1A˜FIG. 1F show intermediate cross sections of a method for forming a MOS transistor of an embodiment of the invention.

FIG. 2 shows a cross action of a rapid thermal process (RTP) chamber.

FIG. 3A˜FIG. 3G show intermediate cross sections of a method for forming a MOS transistor of another embodiment of the invention.

### DETAILED DESCRIPTION OF INVENTION

It is understood that specific embodiments are provided as examples to teach the broader inventive concept, and one of ordinary skill in the art can easily apply the teaching of the present disclosure to other methods or apparatus. The following discussion is only used to illustrate the invention, not limit the invention.

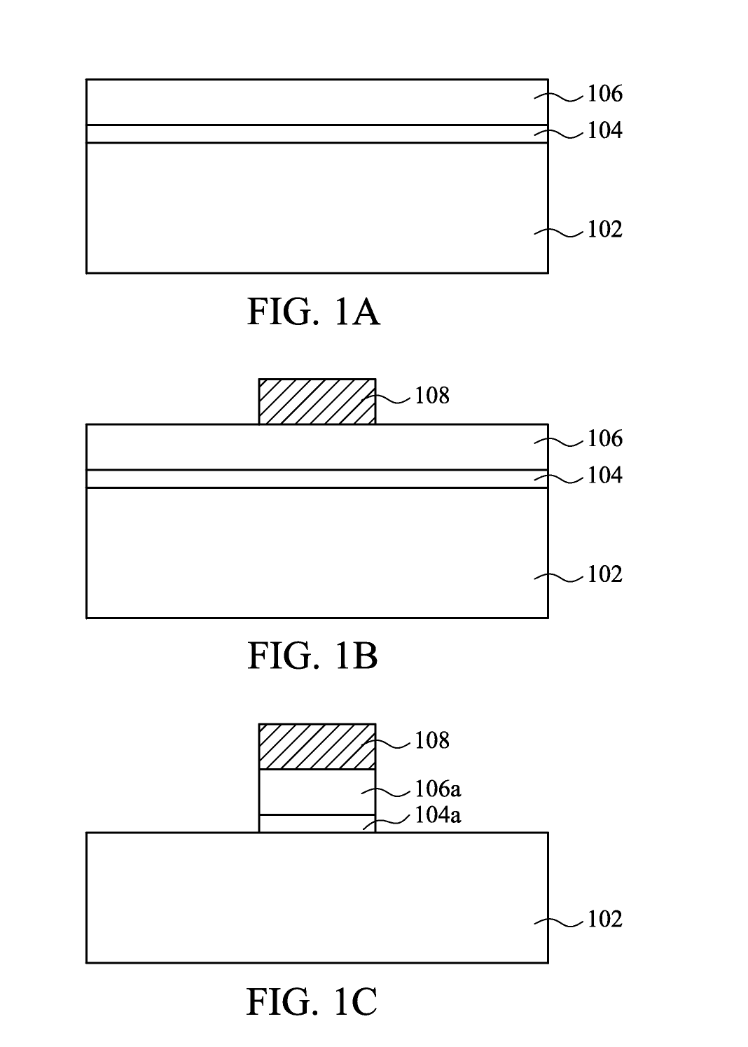

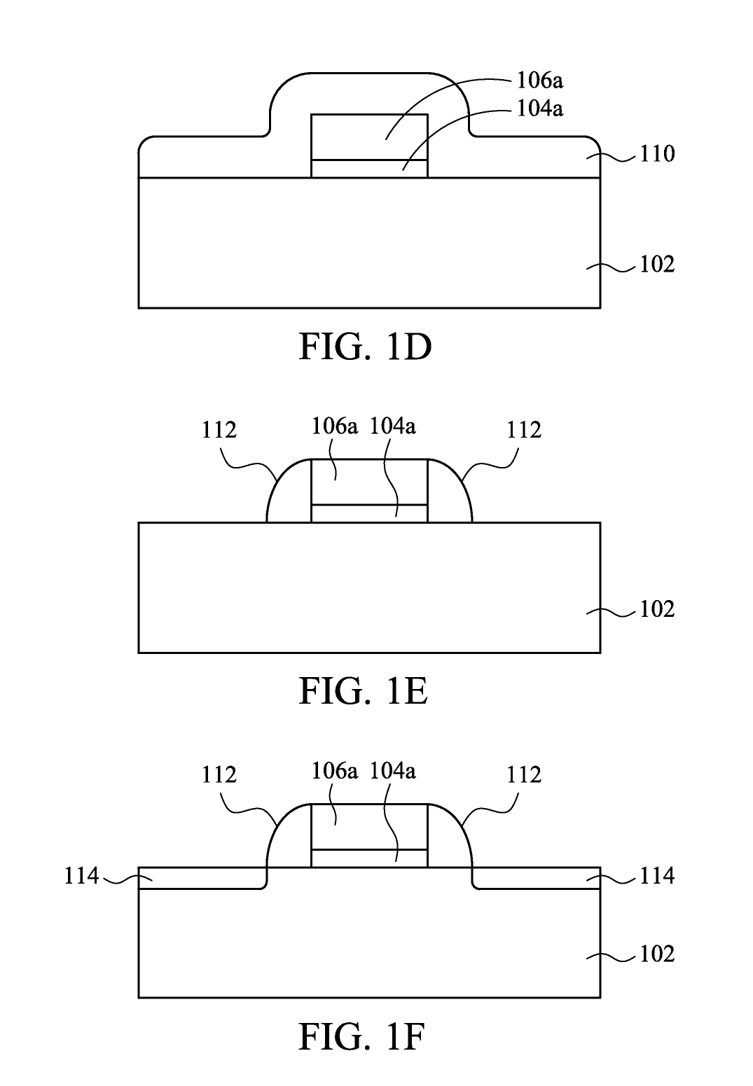

A method for forming a MOS transistor of an embodiment of the invention is illustrated in accordance with FIG. 1A˜FIG. 1F. Referring to FIG. 1A, a substrate 102 suitable for integrated circuit manufacture is provided. In an embodiment of the invention, the substrate 102 is formed of silicon. A gate dielectric layer 104 is formed on the substrate 102. Thereafter, a gate layer 106 is formed on the gate dielectric layer 104. In an embodiment of the invention, the gate dielectric layer 104 can be silicon dioxide, silicon nitride or other high k dielectric layer. The gate layer 106 can be formed of polysilicon, metal or a stack layer of metal and polysilicon.

Referring to FIG. 1B, a photoresist layer 108 is deposited on the gate layer 106 and selectively irradiated using a photolithographic system. Thereafter, the photoresist layer 108 is developed and a portion of the photoresist layer 108 is removed to provide openings in photoresist layer 108. The openings expose portions of the gate layer 106, thereby defining a gate.

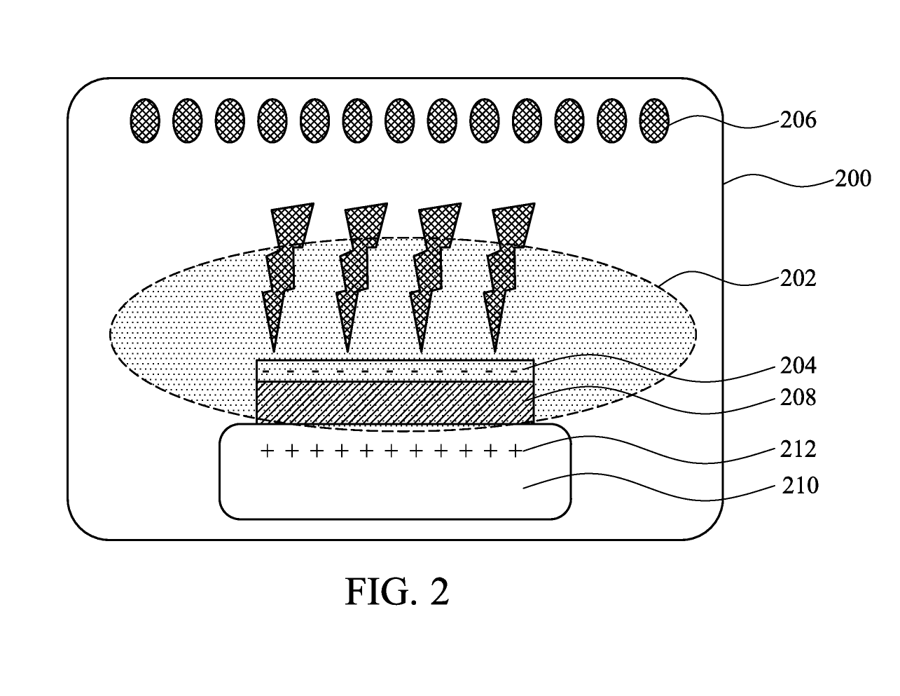

Referring to FIG. 1C, an anisotropic etch is applied that removes the exposed portions of the gate layer 106 and the underlying portions of the gate dielectric layer 104. Desirably, a first dry etch is applied that is highly selective of polysilicon, and a second dry etch is applied that is highly selective of silicon dioxide, using the photoresist layer 108 as an etch mask. After etching occurs, the remaining portion of the gate layer 106 and gate dielectric layer 104 provides a gate electrode 106a with opposing vertical sidewalls and the patterned gate dielectric layer 104a. Preferably, the gate electrode 106a has a length narrower than 90 nm. Referring to FIG. 1D, a spacer layer 110 is deposited on the gate electrode 106a and the substrate 102. In an embodiment of the invention, the spacer layer 110 is formed of tetraethyl orthosilicate (TEOS). Thereafter, referring to FIG. 1E, the spacer layer 110 is anisotropically etched to form a spacer 112 on the sidewall of the gate electrode 106a and the gate dielectric layer 104a. Next, referring to FIG. 2, in an important aspect of the invention, the substrate 208 is input into a rapid thermal process (RTP) chamber 200 which comprises a plurality of lamps 206 to heat the substrate 208, a holder 210 for supporting the substrate 208, and a bias applying system. In the RTP chamber 200, gaseous dopant species 202 are illuminated by the lamps 206 to be excited for transference gaseous dopant species 202 to dopant ions 204. The dopant ions 204 are moved by a bias 212 from the bias applying system to be doped into the substrate 208. In an embodiment of the invention, the applied bias is 10V˜500V. Alternatively, the rapid thermal process can use UV light or a laser to ionize the gaseous dopant species 202. In an embodiment, the doping step and annealing step can be performed simultaneously in the rapid thermal process chamber 200, and minimal or no substrate lattice damage is generated. In an embodiment of the invention, the annealing step heats the substrate 208 to 700° C.˜1200 C. Further, the gaseous dopant species 202 comprise boron or phosphorous. Therefore, as shown in FIG. 1F, a source/drain region 114 with an end adjacent to the spacer 112 is formed in the substrate 208. In an embodiment of the invention, the source/drain region 114 is very shallow, for example having a depth of about 8 nm˜20 nm.

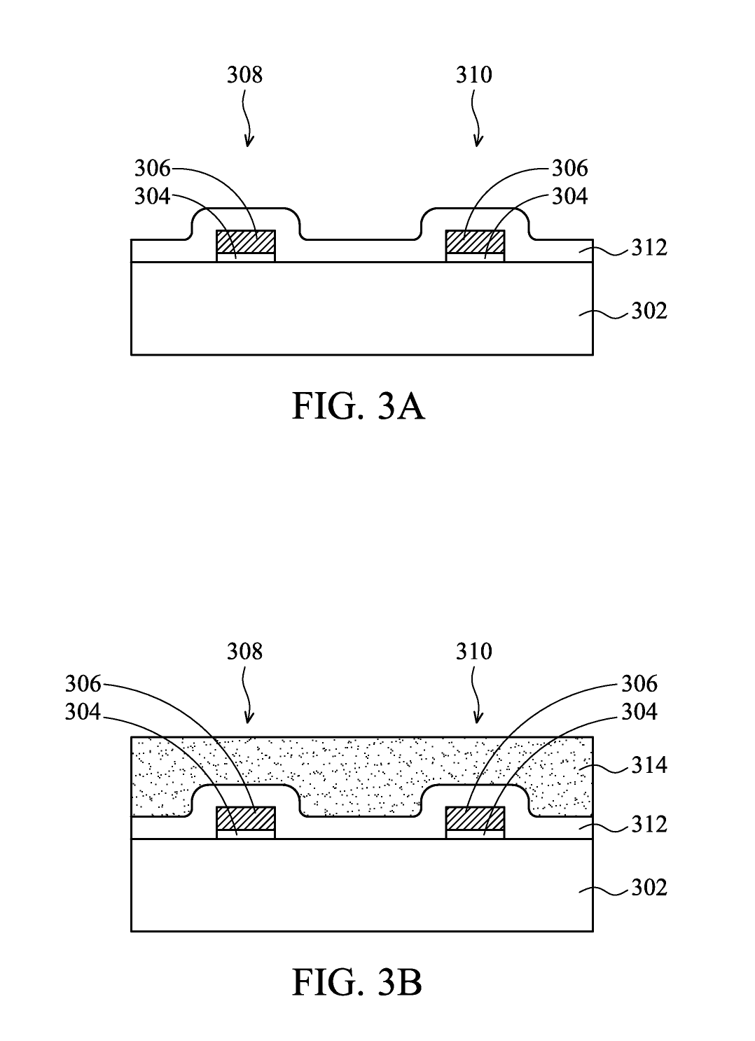

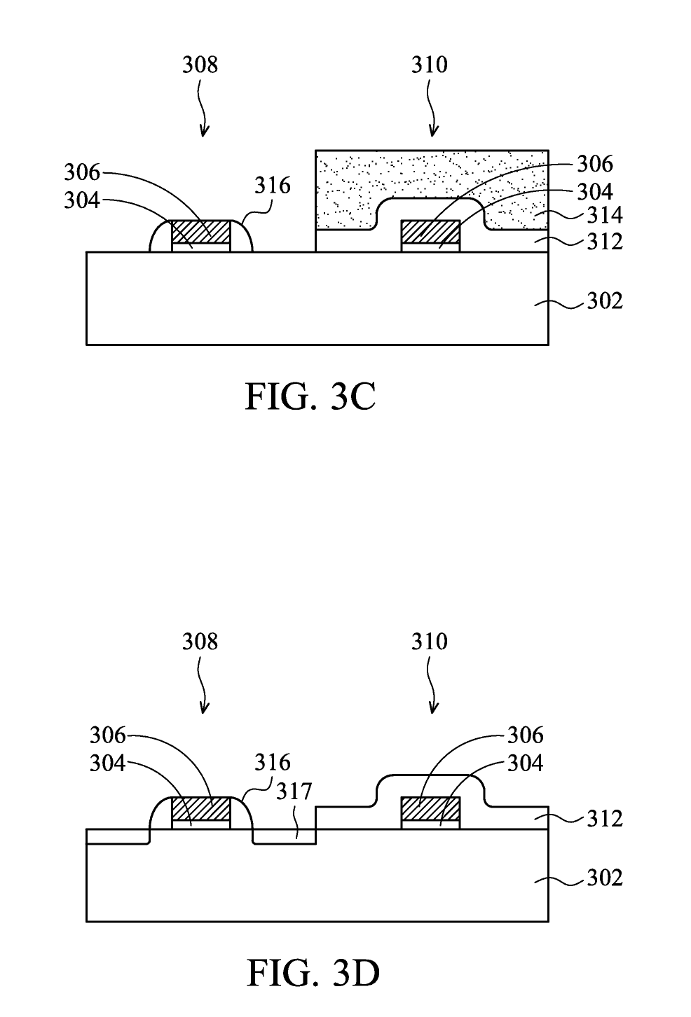

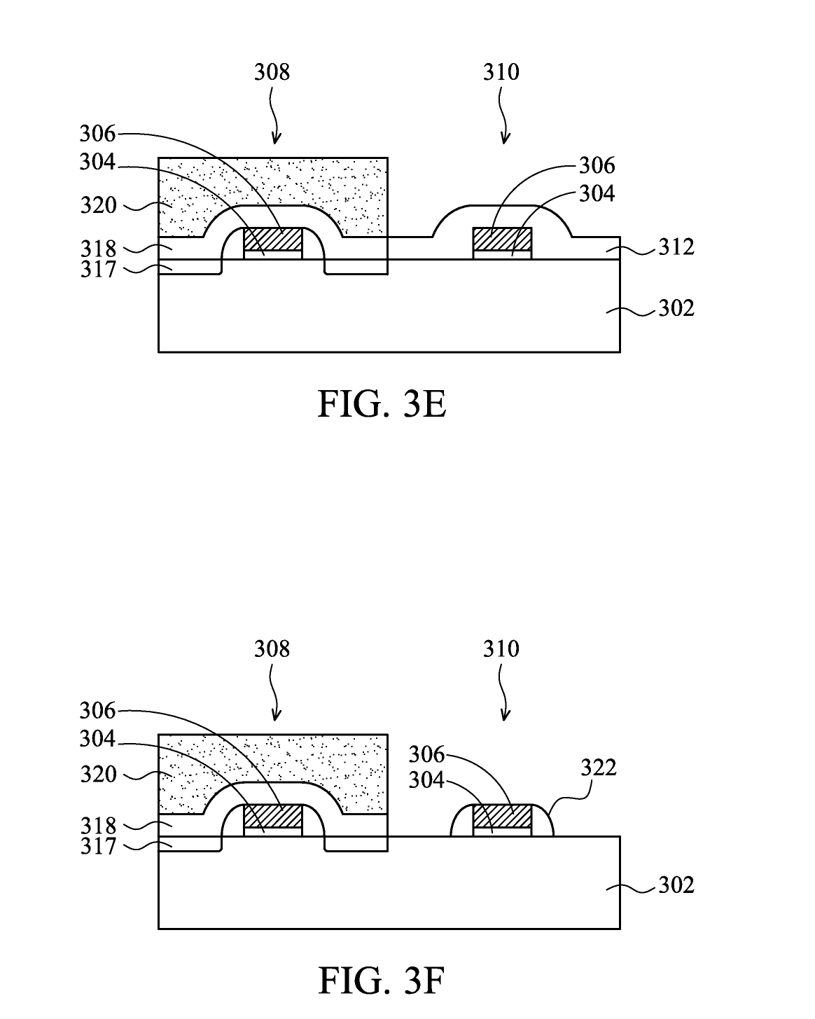

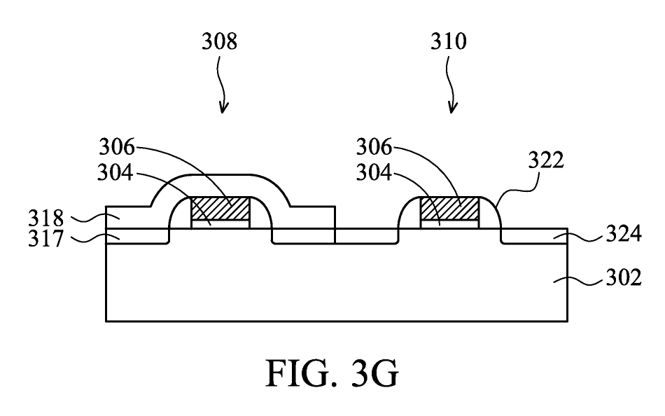

A more complicated structure, having both an NMOSFET and a PMOSFET, may be constructed following the processing steps of FIGS. 3A-3G. Those of ordinary skill in the art will appreciate that the description of these processing steps relies upon knowledge of the processing steps of FIGS. 1A-1F already described. Thus, only those steps needed to describe how to make and use the embodiment resulting from FIGS. 3A-3G are described.

Referring to FIG. 3A, a substrate 302 is provided. A gate dielectric layer and a gate electrode are sequentially formed on the substrate 302 and are then patterned by lithography to form a gate dielectric layer 304 and a gate electrode 306 for an NMOS in the NMOS region 308 and a gate dielectric layer 304 and a gate electrode 306 for a PMOS in the PMOS region 310. Next, a first spacer layer 312 is formed on the substrate 302. In an embodiment of the invention, the first spacer layer 312 can be formed of tetraethyl orthosilicate (TEOS). Referring to FIG. 3B, a first photoresist layer 314 is coated on the first spacer layer 312. Next, referring to FIG. 3C, the first photoresist layer 314 is patterned by performing a lithography process to remove a portion over the NMOS region 308 and leave a portion over the PMOS region 310. Thereafter, an anisotropic etching process is performed to etch the first spacer layer 312 in the NMOS region 308 to form a first spacer 316 on the sidewall of the gate electrode 306 and the gate dielectric layer 304. Next, the first photoresist layer 314 is removed.

Referring to FIG. 3D, the substrate 302 is input into a rapid thermal process (RTP) chamber, wherein gaseous dopant species are illuminated by the lamps to be excited for transference gaseous dopant species to dopant ions. The dopant ions are moved by a bias from the bias applying system to be doped into the substrate 302 to form a first source/drain region 317 for the NMOS using the first spacer layer 312 in the PMOS region 310 as a mask. The gaseous dopant species is n-type so that an NOSFET is created. In an embodiment, the gaseous dopant species comprises phosphorous. Referring to FIG. 3E, a second spacer layer 318 is formed and a second photoresist layer 320 is coated on the second spacer layer 318. In an embodiment of the invention, the second spacer layer 318 is formed of silicon nitride. Next, the second photoresist layer 320 is patterned by performing a lithography process to remove a portion thereof in the PMOS region 310 and leave a portion in the NMOS region 308. Thereafter, an etching process is performed to remove the second spacer layer 318 in the PMOS region 310. Referring to FIG. 3F, an isotropic etching process is performed to etch the first spacer layer 312 in the PMOS region 310 to form a second spacer 322 on the sidewall of the gate electrode 306 and the gate dielectric layer 304. Next, the second photoresist layer 320 is removed. Referring to FIG. 3G, the substrate 302 is input into a rapid thermal process (RTP) chamber, wherein gaseous dopant species are illuminated by the lamps to be excited for transference gaseous dopant species to dopant ions. The dopant ions are moved by a bias from the bias applying system to be doped into the substrate 302 to form a second source/drain region 324 for the PMOS using the second spacer layer 318 in the NMOS region 308 as a mask. The gaseous dopant species is p-type so that a PMOSFET is created. In an embodiment, the gaseous dopant species comprises boron.

The method uses rapid thermal processes to dope source/drain regions and has the features as follows. First, rapid thermal processes can form very shallow source/drain regions fit for deep sub-micron semiconductor processes. Second, doping and annealing steps can be performed simultaneously in a rapid thermal process chamber, and minimal or no substrate lattice damage is generated.

While the invention has been described by way of example and in terms of the preferred embodiments, it is to be understood that the invention is not limited to the disclosed embodiments. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a semiconductor device, comprising:
providing a substrate;
forming a gate dielectric layer on the substrate;
forming a gate electrode on the gate dielectric layer;
forming a spacer on sidewalls of the gate dielectric layer and the gate electrode; and
using a rapid thermal process (RTP) apparatus comprising a plurality of lamps and a bias applying system to dope the substrate to form a source/drain region, wherein in the RTP apparatus, gaseous dopant species are illuminated by the lamps to be excited for transference gaseous dopant species to dopant ions and the dopant ions are moved by a bias from the bias applying system to be doped into the substrate.

2. The method for forming a semiconductor device as claimed in claim 1, further comprising annealing the substrate, wherein the doping and annealing steps are performed simultaneously in the rapid thermal process apparatus.

3. The method for forming a semiconductor device as claimed in claim 2, wherein less or no substrate lattice damage is generated using the rapid thermal process (RTP) apparatus to dope the substrate.

4. The method for forming a semiconductor device as claimed in claim 1, wherein the annealing step heats the substrate to 700° C.˜1200° C.

5. The method for forming a semiconductor device as claimed in claim 1, wherein the applied bias is 10V˜500V.

6. The method for forming a semiconductor device as claimed in claim 1, wherein the spacer is formed of tetraethyl orthosilicate (TEOS).

7. The method for forming a semiconductor device as claimed in claim 1, wherein the gaseous dopant species comprise boron or phosphorous.

8. The method for forming a semiconductor device as claimed in claim 1, wherein the step of forming the gate dielectric layer and forming the gate electrode on the gate dielectric layer comprises:
forming a gate dielectric layer on the substrate;
forming a gate layer on the gate dielectric layer; and
patterning the substrate and the gate layer by lithography.

9. The method for forming a semiconductor device as claimed in claim 1, wherein the step of forming the spacer on sidewalls of the gate dielectric layer and the gate electrode comprises:
forming a spacer layer on the gate electrode and the gate dielectric layer; and
performing an anisotropic etching to etch the spacer layer.

10. A method for forming a semiconductor device, comprising:
providing a substrate comprising an NMOS region and a PMOS region;
forming a gate dielectric layer and a gate electrode on the NMOS region and the PMOS region of the substrate;
forming a first spacer layer on the gate electrode and the substrate;
forming a first photoresist layer over the PMOS region of the substrate;
etching the first spacer layer in the NMOS region to form a first spacer using the first photoresist layer in the PMOS region as a mask;
removing the first photoresist layer;
using a rapid thermal process (RTP) apparatus comprising a plurality of lamps and a bias applying system to dope the substrate to form a first source/drain region in the NMOS region, wherein first gaseous dopant species are illuminated by the lamps to be excited for transference gaseous dopant species to first dopant ions and the first dopant ions are moved by a bias from the bias applying system to be doped into the NMOS region of substrate;
forming a second spacer layer over the NMOS region and the PMOS region of the substrate;
forming a second photoresist layer over the NMOS region of the substrate;
etching the second spacer layer in the PMOS region using the second photoresist layer as a mask;
etching the first spacer layer in the PMOS region to form a second spacer using the second photoresist layer in the NMOS region as a mask;
removing the second photoresist layer; and
using the rapid thermal process (RTP) apparatus to dope the substrate to form a source/drain region in the PMOS region, wherein second gaseous dopant species are illuminated by the lamps to be excited for transference gaseous dopant species to second dopant ions and the second dopant ions are moved by a bias from the bias applying system to be doped into the PMOS region of substrate.

11. The method for forming a semiconductor device as claimed in claim 10, further comprising annealing the substrate, wherein the doping and annealing steps are performed simultaneously in the rapid thermal process apparatus.

12. The method for forming a semiconductor device as claimed in claim 11, wherein less or no substrate lattice damage is generated using the rapid thermal process (RTP) apparatus to dope the substrate.

13. The method for forming a semiconductor device as claimed in claim 12, wherein the annealing step heats the substrate to 700° C.˜1200° C.

14. The method for forming a semiconductor device as claimed in claim 10, wherein the applied bias is 10V˜500V.

15. The method for forming a semiconductor device as claimed in claim 10, wherein the first spacer layer is formed of tetraethyl orthosilicate (TEOS) and the second spacer layer is formed of silicon nitride.

16. The method for forming a semiconductor device as claimed in claim 10, wherein the first gaseous dopant species comprise phosphorous.

17. The method for forming a semiconductor device as claimed in claim 10, wherein the second gaseous dopant species comprise boron.

18. The method for forming a semiconductor device as claimed in claim 10, wherein the step of forming the gate dielectric layer and forming the gate electrode on the gate dielectric layer comprises:
forming a gate dielectric layer on the substrate;
forming a gate layer on the gate dielectric layer; and
patterning the substrate and the gate layer by lithography.
